(19) United States
(12) Patent Application Publication
(10) Pub. No.: US 2025/0246412 A1
(43) Pub. Date: Jul. 31, 2025

(54) SUBSTRATE PROCESSING METHOD AND SUBSTRATE PROCESSING APPARATUS

(71) Applicant: Tokyo Electron Limited, Tokyo (JP)

(72) Inventor: Fumiya TAKATA, Miyagi (JP)

(73) Assignee: Tokyo Electron Limited, Tokyo (JP)

(21) Appl. No.: 19/185,246

(22) Filed: Apr. 22, 2025

Related U.S. Application Data
(63) Continuation of application No. PCT/JP2023/037261, filed on Oct. 13, 2023.

(30) Foreign Application Priority Data
Oct. 27, 2022 (JP) 2022-172580

(51) Int. Cl. H01J 37/32

(52) U.S. Cl. CPC H01J 37/32449; H01J 2237/3321; H01J 2237/334

(57) ABSTRACT

A substrate processing method includes: (a) preparing a substrate having a first region containing a first material, and a second region containing a second material different from the first material; (b) forming a metal-containing deposit on the first region by using a first plasma generated from a first processing gas containing at least one of carbon and hydrogen, fluorine, and metal; (c) modifying at least the surface of the metal-containing deposit by using a second plasma generated from a second processing gas different from the first processing gas, after (b); and (d) repeating (b) and (c).

### CROSS-REFERENCE TO RELATED APPLICATIONS

This application is a continuation application of International Patent Application No. PCT/JP2023/037261, filed on Oct. 13, 2023, which claims priority from Japanese Patent Application No. 2022-172580, filed on Oct. 27, 2022, with the Japan Patent Office, all of which are incorporated herein in their entireties by reference.

### TECHNICAL FIELD

An embodiment of the present disclosure relates to a substrate processing method and a substrate processing apparatus.

### BACKGROUND

Japanese Patent Application Laid-Open Publication No. H09-050984 discloses a method of etching an insulating film by using plasma. In this method, etching is performed while a conductive layer is formed on the surface of an insulating film during the etching. In the etching, plasma generated from a mixed gas of WF₆ and C₄F₈ is used.

### SUMMARY

In one embodiment, a substrate processing method includes: (a) preparing a substrate having a first region containing a first material, and a second region containing a second material different from the first material; (b) forming a metal-containing deposit on the first region by using a first plasma generated from a first processing gas containing at least one of carbon and hydrogen, fluorine, and metal; (c) modifying at least the surface of the metal-containing deposit by using a second plasma generated from a second processing gas different from the first processing gas, after (b); and (d) repeating (b) and (c).

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 a view schematically illustrating a substrate processing apparatus according to one embodiment.

FIG. 2 is a view schematically illustrating the substrate processing apparatus according to one embodiment.

FIG. 3 is a flow chart of a substrate processing method according to one embodiment.

FIG. 4 is an enlarged cross-sectional view of a part of a substrate example to which the method of FIG. 3 is applicable.

FIG. 5 is a cross-sectional view illustrating one step of the substrate processing method according to one embodiment.

FIG. 6 is a cross-sectional view illustrating one step of the substrate processing method according to one embodiment.

FIG. 7 is a cross-sectional view illustrating one step of the substrate processing method according to one embodiment.

FIG. 8 is a cross-sectional view illustrating one step of the substrate processing method according to one embodiment.

FIG. 9 is a cross-sectional view illustrating one step of the substrate processing method according to one embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, various embodiments will be described in detail with reference to drawings. Also, in the drawings, the same or corresponding portions shall be given the same reference numerals.

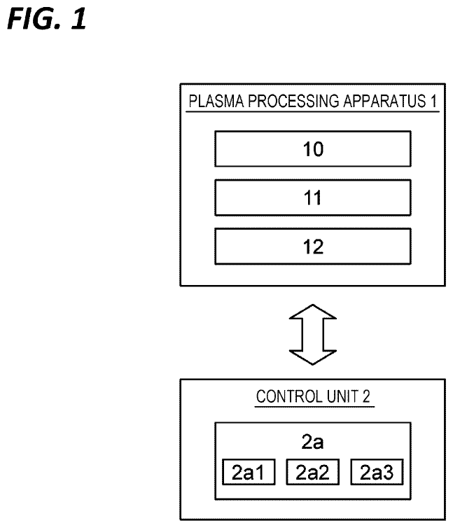

FIG. 1 is a view illustrating a configuration example of a plasma processing system. In one embodiment, the plasma processing system includes a plasma processing apparatus 1 and a control unit 2. The plasma processing system is an example of a substrate processing system, and the plasma processing apparatus 1 is an example of a substrate processing apparatus. The plasma processing apparatus 1 includes a plasma processing chamber 10, a substrate support unit 11 and a plasma generation unit 12. The plasma processing chamber 10 has a plasma processing space. Also, the plasma processing chamber 10 includes at least one gas supply port for supplying at least one processing gas to the plasma processing space, and at least one gas outlet for discharging the gas from the plasma processing space. The gas supply port is connected to a gas supply 20 to be described below, and the gas outlet is connected to an exhaust system 40 to be described below. The substrate support unit 11 is disposed within the plasma processing space, and has a substrate supporting surface for supporting a substrate.

The plasma generation unit 12 is configured to generate plasma from at least one processing gas supplied into the plasma processing space. The plasma formed in the plasma processing space may be, for example, capacitively-coupled plasma (CCP), inductively-coupled plasma (ICP), electron-cyclotron-resonance plasma (ECR plasma), helicon wave-excited plasma (HWP) or surface wave plasma (SWP). Also, various types of plasma generation units, including an alternating current (AC) plasma generation unit and a direct current (DC) plasma generation unit, may be used. In one embodiment, the AC signal (AC power) used in the AC plasma generation unit has a frequency within a range of 100 kHz to 10 GHz. Therefore, AC signals include radio frequency (RF) signals and microwave signals. In one embodiment, the RF signal has a frequency within a range of 100 kHz to 150 MHz.

The control unit 2 processes computer-executable instructions that cause the plasma processing apparatus 1 to execute various steps described in the present disclosure. The control unit 2 may be configured to control each element of the plasma processing apparatus 1 to execute various steps described herein. In one embodiment, the control unit 2 may be partially or entirely included in the plasma processing apparatus 1. The control unit 2 may include a processor 2a1, a storage 2a2 and a communication interface 2a3. The control unit 2 is implemented by, for example, a computer 2a. The processor 2al may be configured to perform various control operations by reading a program from the storage 2a2 and executing the read program. This program may be stored in the storage 2a2 in advance, or may be acquired via a medium if necessary. The acquired program is stored in the storage 2a2, and is read from the storage 2a2 by the processor 2al and then is executed. The medium may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

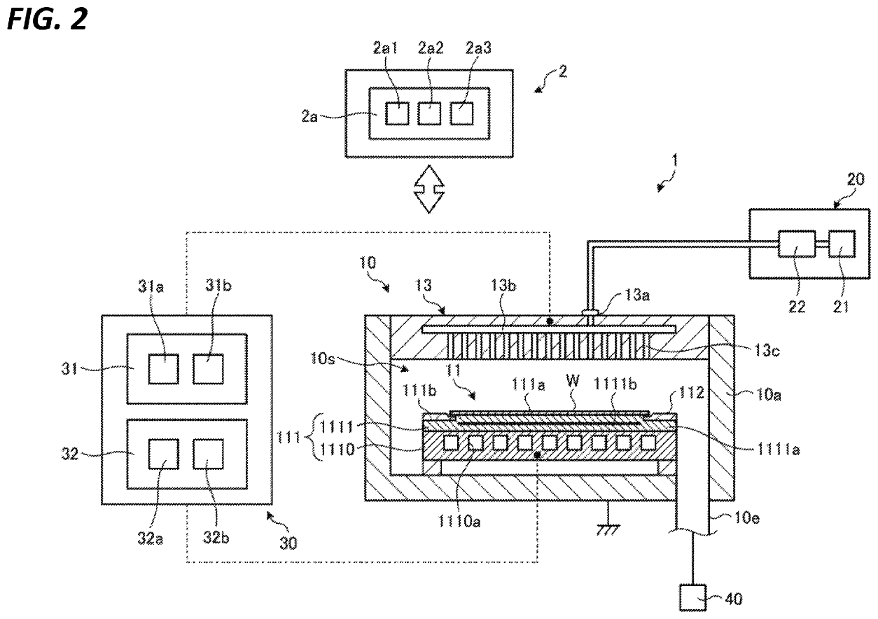

Hereinafter, descriptions will be made on a configuration example of an inductively-coupled plasma processing apparatus as an example of the plasma processing apparatus 1. FIG. 2 is a view illustrating a configuration example of an inductively-coupled plasma processing apparatus.

The inductively-coupled plasma processing apparatus 1 includes the plasma processing chamber 10, the gas supply 20, a power supply 30 and the exhaust system 40. Also, the plasma processing apparatus 1 includes the substrate support unit 11 and a gas introduction unit. The gas introduction unit is configured to introduce at least one processing gas into the plasma processing chamber 10. The gas introduction unit includes a shower head 13. The substrate support unit 11 is disposed inside the plasma processing chamber 10. The shower head 13 is disposed above the substrate support unit 11. In one embodiment, the shower head 13 constitutes at least a part of the ceiling of the plasma processing chamber 10. The plasma processing chamber 10 has a plasma processing space 10s defined by the shower head 13, a side wall 10a of the plasma processing chamber 10 and the substrate support unit 11. The plasma processing chamber 10 is grounded. The shower head 13 and the substrate support unit 11 are electrically insulated from the housing of the plasma processing chamber 10.

The substrate support unit 11 includes a main body 111 and a ring assembly 112. The main body 111 has a central region 111a for supporting a substrate W and an annular region 111b for supporting the ring assembly 112. The wafer is an example of the substrate W. In plan view, the annular region 111b of the main body 111 surrounds the central region 111a of the main body 111. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate supporting surface for supporting the substrate W, and the annular region 111b is also called a ring supporting surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed within the ceramic member 1111a. The ceramic member 1111a has the central region 111a. In one embodiment, the ceramic member 1111a also has the annular region 111b. Also, another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Also, at least one RF/DC electrode coupled to an RF power supply 31 and/or a DC power supply 32 to be described below may be disposed within the ceramic member 1111a. In this case, at least one RF/DC electrode functions as a lower electrode. When a bias RF signal and/or a DC signal to be described below is supplied to at least one RF/DC electrode, the RF/DC electrode is also called a bias electrode. Also, the conductive member of the base 1110 and at least one RF/DC electrode may function as a plurality of lower electrodes. Also, the electrostatic electrode 1111b may function as a lower electrode. Therefore, the substrate support unit 11 includes at least one lower electrode.

The ring assembly 112 includes one or more annular members. In one embodiment, one or more annular members include one or more edge rings and at least one cover ring. The edge ring is made of a conductive material or an insulating material, and the cover ring is made of an insulating material.

A Iso, the substrate support unit 11 may include a temperature control module configured to control at least one of the electrostatic chuck 1111, the ring assembly 112, and the substrate, to a target temperature. The temperature control module may include a heater, a heat transfer medium, a flow path 1110a, or a combination thereof. A heat transfer fluid such as brine or gas flows through the flow path 1110a. In one embodiment, the flow path 1110a is formed within the base 1110, and one or more heaters are disposed within the ceramic member 1111a of the electrostatic chuck 1111. Also, the substrate support unit 11 may include a heat transfer gas supply configured to supply a heat transfer gas to the gap between the back surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c through the gas diffusion chamber 13b. Also, the shower head 13 includes at least one upper electrode. Also, in addition to the shower head 13, the gas introduction unit may include one or more side gas injectors (SGIs) attached to one or more openings formed in the side wall 10a.

The gas supply 20 may include at least one gas source 21 and at least one flow controller 22. In one embodiment, the gas supply 20 is configured to supply at least one processing gas from each corresponding gas source 21 to the shower head 13 through each corresponding flow controller 22. Each flow controller 22 may include, for example, a mass flow controller or a pressure control-type flow controller. Furthermore, the gas supply 20 may include at least one flow modulation device that modulates the flow rate of at least one processing gas or makes a pulse.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. Accordingly, plasma is formed from at least one processing gas supplied to the plasma processing space 10s. Therefore, the RF power supply 31 may function as at least a part of the plasma generation unit 12. Also, when a bias RF signal is supplied to at least one lower electrode, a bias potential is generated in the substrate W, and ion components in the formed plasma may be attracted to the substrate W.

In one embodiment, the RF power supply 31 includes a first RF generation unit 31a and a second RF generation unit 31b. The first RF generation unit 31a is coupled to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generation unit 31a may be configured to generate source RF signals having different frequencies. One or more generated source RF signals are supplied to at least one lower electrode and/or at least one upper electrode.

The second RF generation unit 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generation unit 31b may be configured to generate bias RF signals having different frequencies. One or more generated bias RF signals are supplied to at least one lower electrode. Also, in various embodiments, at least one of the source RF signal and the bias RF signal may be pulsed.

Also, the power supply 30 may include the DC power supply 32 coupled to the plasma processing chamber 10. The DC power supply 32 includes a first DC generation unit 32a and a second DC generation unit 32b. In one embodiment, the first DC generation unit 32a is connected to at least one lower electrode, and is configured to generate a first DC signal. The generated first DC signal is applied to at least one lower electrode. In one embodiment, the second DC generation unit 32b is connected to at least one upper electrode, and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulses may have a pulse waveform of a rectangle, a trapezoid, a triangle, or a combination thereof. In one embodiment, a waveform generation unit for generating a sequence of voltage pulses from DC signals is connected between the first DC generation unit 32a and at least one lower electrode. Therefore, the first DC generation unit 32a and the waveform generation unit constitute a voltage pulse generation unit. When the second DC generation unit 32b and the waveform generation unit constitute the voltage pulse generation unit, the voltage pulse generation unit is connected to at least one upper electrode. The voltage pulse may have a positive polarity or may have a negative polarity. Also, the sequence of voltage pulses may include one or more positive voltage pulses and one or more negative voltage pulses within one period. Also, the first and second DC generation units 32a and 32b may be provided in addition to the RF power supply 31, or the first DC generation unit 32a may be provided instead of the second RF generation unit 31b.

The exhaust system 40 may be connected to, for example, a gas outlet 10e formed at the bottom of the plasma processing chamber 10. The exhaust system 40 may include a pressure regulation valve and a vacuum pump. By the pressure regulation valve, the pressure within the plasma processing space 10s is adjusted. The vacuum pump may include a turbomolecular pump, a dry pump, or a combination thereof.

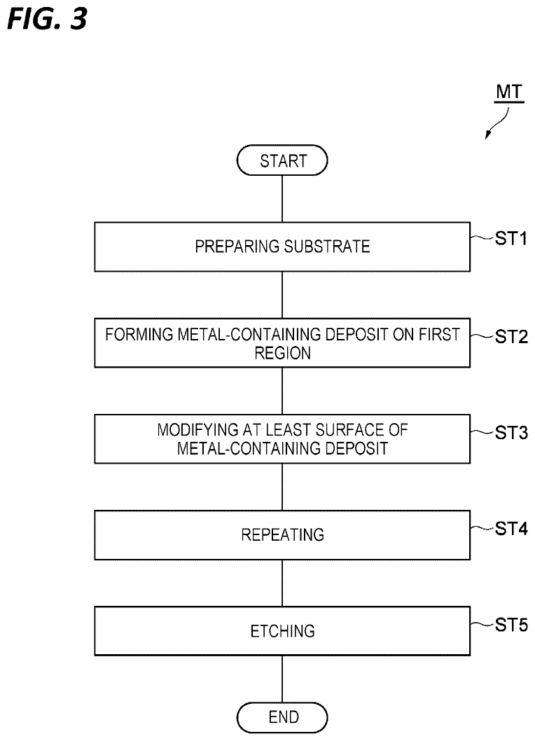

FIG. 3 is a flow chart of a substrate processing method according to one embodiment. The substrate processing method MT1 illustrated in FIG. 3 (hereinafter, referred to as a “method MT1”) may be executed by the plasma processing apparatus 1 of the embodiment. The method MT1 may be applied to the substrate W.

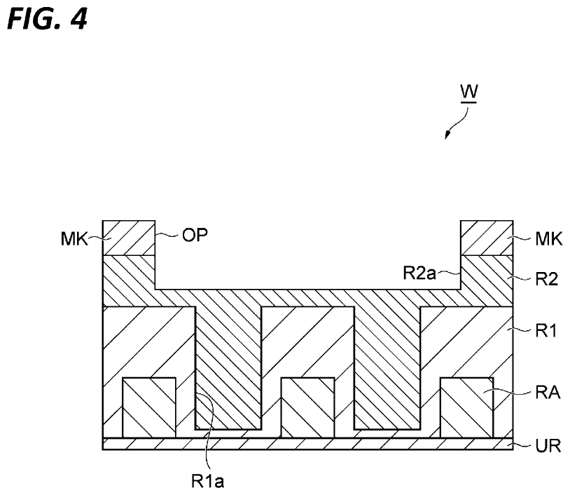

FIG. 4 is an enlarged cross-sectional view of a part of a substrate example to which the method of FIG. 3 is applicable. As illustrated in FIG. 4, in one embodiment, the substrate W includes a first region R1 and a second region R2. The first region R1 may have at least one recess R1a. The first region R1 may have a plurality of recesses R1a. Each recess R1a may be a recess for forming a contact hole. The second region R2 may be present in the recess R1a or may be embedded in the recess R1a. The second region R2 may be provided to cover the first region R1.

The first region R1 contains a first material. The first material may include silicon and nitrogen. The first region R1 may include silicon nitride (SiNₓ). The first region R1 may be a region formed by, for example, CV D, etc. or may be a region obtained by nitriding silicon. The first region R1 may include a first portion containing silicon nitride (SiNₓ), and a second portion containing silicon carbide (SIC). In this case, the first portion has the recess R1a.

The second region R2 contains a second material. The second material is different from the first material. The second material may include silicon and oxygen. The second region R2 may include silicon oxide (SiOₓ). The second region R2 may be a region formed by, for example, CVD, etc. or may be a region obtained by oxidizing silicon. The second region R2 may have a recess R2a. The recess R2a has a width larger than the width of the recess R1a.

The substrate W may include an underlayer region UR, and at least one raised region RA provided on the underlayer region UR. The underlayer region UR and at least one raised region RA are covered by the first region R1. The underlayer region UR may contain silicon. A plurality of raised regions RA is located on the underlayer region UR. The recess R1a of the first region R1 is located between the raised regions RA. Each raised region RA may form a gate region of a transistor.

The substrate W may include a mask MK. The mask M K is provided on the second region R2. The mask MK may contain metal or silicon. The mask MK may have an opening OP. The opening OP corresponds to the recess R2a of the second region R2.

Hereinafter, the method MT1 will be described with reference to FIGS. 3 to 9, taking as an example a case where the method MT1 is applied to the substrate W by using the plasma processing apparatus 1 of the embodiment. FIGS. 3 to 9 are cross-sectional views illustrating one process of a substrate processing method according to one embodiment. When the plasma processing apparatus 1 is used, the control unit 2 controls each part of the plasma processing apparatus 1 such that the method MT1 may be executed in the plasma processing apparatus 1. In the method MT1, as illustrated in FIG. 2, the substrate W on the substrate support unit 11 disposed in the plasma processing chamber 10 is processed.

As illustrated in FIG. 3, the method MT1 may include step ST1, step ST2, step ST3, step ST4, and step ST5. Step ST1 to step ST5 may be sequentially executed. The method MT1 may not include step ST5.

### (Step ST1)

In step ST1, the substrate W illustrated in FIG. 4 is prepared. The substrate W may be supported by the substrate support unit 11 within the plasma processing chamber 10. The substrate W may have the shape illustrated in FIG. 4 as a result of plasma etching, or may have the shape illustrated in FIG. 4 when it is initially provided to the plasma processing chamber 10. In step ST1, the second region R2 may be provided to cover the first region R1. In step ST1, the second region R2 may be etched such that the top surface of the first region R1 and the top surface of the second region R2 are exposed.

### (Step ST2)

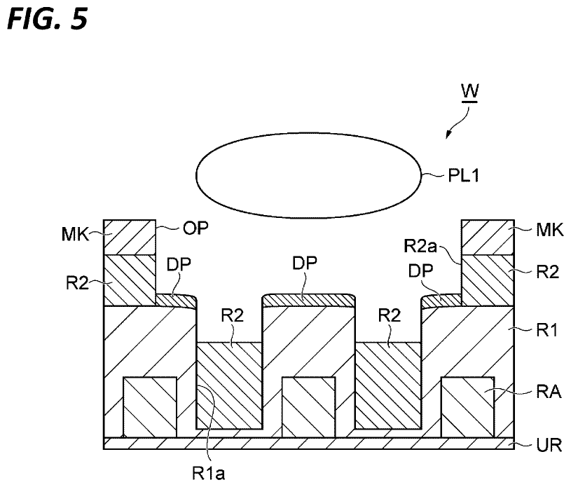

In step ST2, as illustrated in FIG. 5, a metal-containing deposit DP is formed on the first region R1 by using first plasma PL1 generated from a first processing gas. The second region R2 may be etched by the first plasma PL1. The metal-containing deposit DP is unlikely to be formed on the second region R2. At the end of step ST2, the supply of the first processing gas is stopped.

The first processing gas contains at least one of carbon and hydrogen, fluorine, and metal. The metal may include at least one selected from tungsten and molybdenum.

The first processing gas may contain at least one of a carbon-containing gas and a hydrogen-containing gas, and a metal-containing gas. Fluorine may be contained in the carbon-containing gas, the hydrogen-containing gas, or the metal-containing gas.

The carbon-containing gas contained in the first processing gas may include at least one selected from hydrocarbon (CₓH_{y}) gas, fluorocarbon (CₓF_{y}) gas, hydrofluorocarbon gas (CₓH_{y}F_{z}) and carbon monoxide (CO) gas. The hydrocarbon (CₓH_{y}) gas may include at least one selected from CH₄ gas, C₂H₆ gas, C₂H₄ gas, C₃H₈ gas, C₃H₆ gas, C₄H₈ gas, and C₄H₆ gas. The fluorocarbon (CₓF_{y}) gas may include at least one selected from CF₄ gas, C₃F₆ gas, C₃F₈ gas, C₄F₈ gas, and C₄F₆ gas. The hydrofluorocarbon (CₓH_{y}F_{z}) gas may include at least one selected from CH₂F₂ gas, CHF₃ gas, and CH₃F gas. x, y, and z are natural numbers.

The hydrogen-containing gas contained in the first processing gas may include at least one selected from hydrogen gas, B₂H₆ gas, SiH₄ gas, and HF gas.

The metal-containing gas contained in the first processing gas may include at least one selected from tungsten halide gas and molybdenum halide gas. The tungsten halide gas may include at least one selected from tungsten hexafluoride (WF₆) gas, tungsten hexabromide (WBr₆) gas, tungsten hexachloride (WCl₆) gas, and WF₅Cl gas. The metal-containing gas may include hexacarbonyl tungsten (W(CO)₆) gas. The molybdenum halide gas may include at least one selected from molybdenum hexafluoride (MoF₆) gas and molybdenum hexachloride (MoCl₆) gas.

The first processing gas may further contain a noble gas. The noble gas may include at least one selected from argon gas, helium gas, xenon gas, and neon gas.

The metal-containing deposit DP may contain metal oxide. The metal oxide may include at least one selected from tungsten oxide and molybdenum oxide. The metal-containing deposit DP may include metal nitride. The metal nitride may include at least one selected from tungsten nitride and molybdenum nitride.

### (Step ST3)

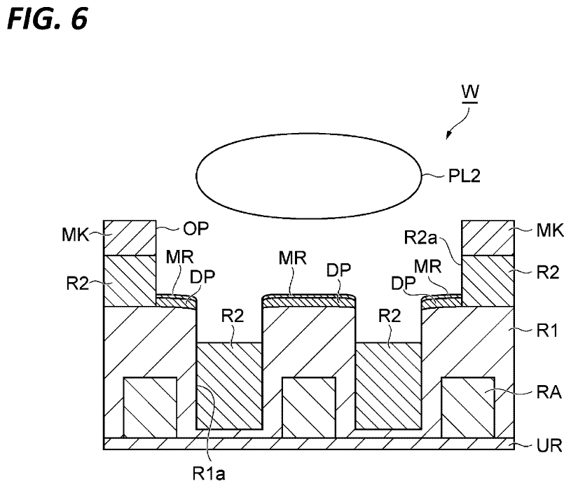

In step ST3, as illustrated in FIG. 6, at least the surface of the metal-containing deposit DP is modified by using second plasma PL2 generated from a second processing gas. A part of the metal-containing deposit DP may be modified by the second plasma PL2, or the entire metal-containing deposit DP may be modified. A modified region MR is formed from the metal-containing deposit DP through modification of the metal-containing deposit DP. The modified region MR may be a metal region or a metal layer. The modified region MR may be a tungsten layer or a molybdenum layer. The second region R2 may not be etched by the second plasma PL2. At the end of step ST3, the supply of the second processing gas is stopped.

The second processing gas of step ST3 is different from the first processing gas of step ST2. The second processing gas may contain a hydrogen-containing gas. The hydrogen-containing gas may include at least one selected from hydrogen gas, B₂H₆ gas, SiH₄ gas, SiH₂F₂ gas, GeH₄ gas, and HF gas. When the metal-containing deposit DP contains metal oxide, the second processing gas may contain a reducing gas that reduces metal oxide. An example of the reducing gas includes a hydrogen-containing gas. The second processing gas may not contain metal, or may not contain fluorine.

The processing time of step ST3 may be shorter than the processing time of step ST2.

### (Step ST4)

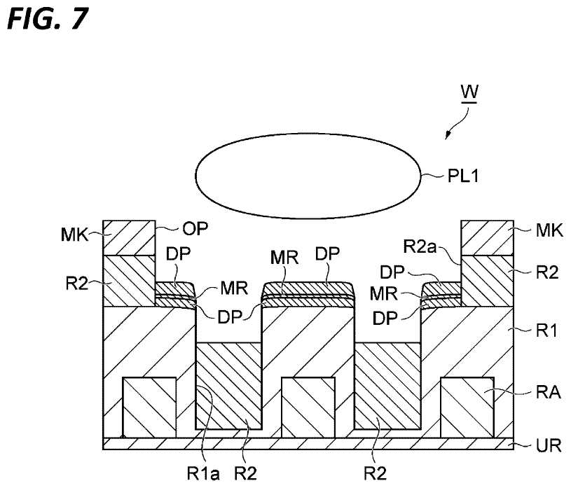

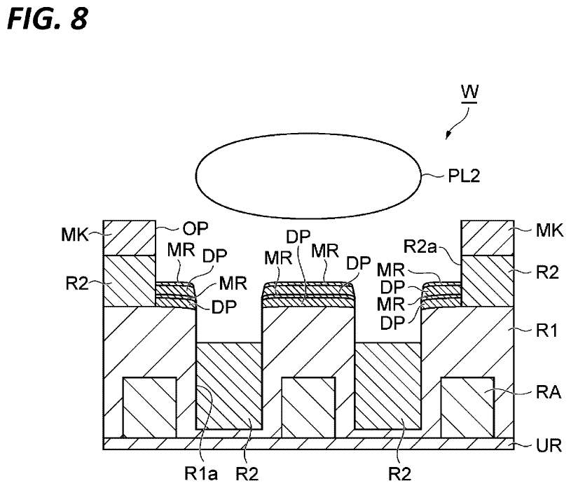

In step ST4, step ST2 and step ST3 are repeated. In step ST2 during step ST4, as illustrated in FIG. 7, a metal-containing deposit DP is formed on the modified region MR by using the first plasma PL1. In step ST3 during step ST4, as illustrated in FIG. 8, at least the surface of the metal-containing deposit DP is modified by using the second plasma PL2. Accordingly, a modified region MR is formed from the metal-containing deposit DP. When a part of the metal-containing deposit DP is modified, the upper portion including the surface of the metal-containing deposit DP is modified, and the remaining portion (lower portion) of the metal-containing deposit DP is not modified. In this case, through step ST4, the metal-containing deposit DP and the modified region MR are alternately stacked.

### (Step ST5)

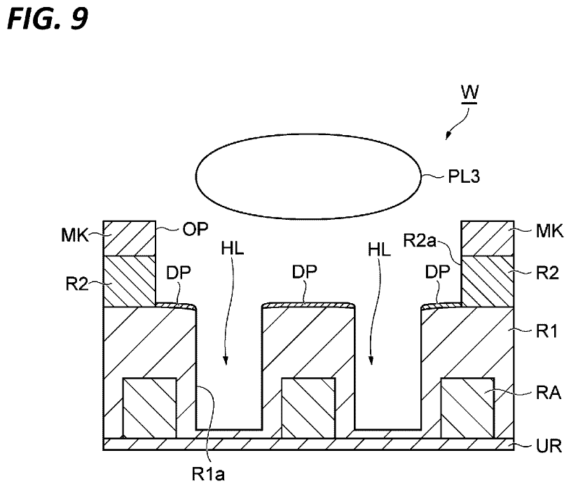

In step ST5, as illustrated in FIG. 9, the second region R2 is etched by using third plasma PL3 generated from a third processing gas.

The third processing gas of step ST5 is different from the first processing gas of step ST2 and the second processing gas of step ST3. The third processing gas may contain a fluorine-containing gas. The fluorine-containing gas may include at least one selected from fluorocarbon gas and hydrofluorocarbon gas. The fluorocarbon (CₓF_{y}) gas may include at least one selected from CF₄ gas, C₃F₆ gas, C₃F₈ gas, C₄F₈ gas, and C₄F₆ gas. The hydrofluorocarbon (CₓH_{y}F_{z}) gas may include at least one selected from CH₂F₂ gas, CHF₃ gas, and CH₃F gas. x, y, and z are natural numbers.

In step ST5, the first region R1 is covered with the modified region MR and thus is difficult to etch. The second region R2 is easier to etch than the first region R1. As the second region R2 is etched, as illustrated in FIG. 9, a contact hole HL is formed. The contact hole HL corresponds to the recess R1a in the first region R1. In this manner, step ST1 to step ST5 may be performed in etching a self-aligned contact (SAC) structure. After the second region R2 in the recess R1a is removed, the metal-containing deposit DP or the modified region MR may remain on the first region R1. In this case, in step ST5, the etching of the first region R1 is suppressed. The metal-containing deposit DP or the modified region MR may be removed by cleaning after step ST5.

Through the method MT1 discussed above, the modified region MR is formed in step ST3. After that, in step ST2 during step ST4, the metal-containing deposit DP is further formed on the modified region MR. A thicker metal-containing deposit DP is formed on the modified region MR compared to when the modified region MR is not present. Therefore, by adjusting the number of repetitions of step ST2 and step ST3, it is possible to control the thickness of the metal-containing deposit (the metal-containing deposit DP or the modified region MR) formed on the first region R1. As a result, a sufficiently thick metal-containing deposit may be formed such that the metal-containing deposit on the first region R1 may remain after the etching of step ST5.

Hereinafter, descriptions will be made on various experiments performed to evaluate the method MT1. The experiments to be described below do not limit the present disclosure.

### First Experiment

In the first experiment, a substrate W, which includes a first region R1 containing silicon nitride (SiNₓ) and a second region R2 containing silicon oxide (SiOₓ), was prepared. After that, step ST2 and step ST3 were carried out on the substrate W by using the plasma processing apparatus 1.

In step ST2, first plasma PL1 was generated from a first processing gas. By using the first plasma PL1, a metal-containing deposit DP was formed on the first region R1 while the second region R2 was etched. The first processing gas is a mixed gas of tungsten hexafluoride (WF₆) gas, C₄F₈ gas, argon (Ar) gas, and hydrogen (H₂) gas. The metal-containing deposit DP contains tungsten oxide.

In step ST3, second plasma PL2 was generated from a second processing gas. By using the second plasma PL2, the metal-containing deposit DP was modified to form a modified region MR. The second processing gas is hydrogen (H₂) gas. The modified region MR is a tungsten layer.

### Second Experiment

In a second experiment, the same method as the method for the first experiment was executed except that step ST2 and step ST3 were repeated once after step ST3. Each of steps ST2 and ST3 was executed twice.

### Third Experiment

In a third experiment, the same method as the method for the first experiment was executed except that step ST2 and step ST3 were repeated twice after step ST3. Each of steps ST2 and ST3 was executed three times.

### Experiment Result

TEM images of the cross sections of the substrate W, on which the method was executed in the first experiment to the third experiment, were observed. From the TEM images, the thickness of the metal-containing deposit formed on the first region R1 was measured. In the first experiment, the thickness of the metal-containing deposit was 2.7 nm. In the second experiment, the thickness of the metal-containing deposit was 3.5 nm. In the third experiment, the thickness of the metal-containing deposit was 3.9 nm. Therefore, it can be found that it is possible to control the thickness of the metal-containing deposit by adjusting the number of repetitions of step ST2 and step ST3.

Although various embodiments have been described above, various additions, omissions, substitutions, and modifications may be made without being limited to the above-described embodiments. Also, it is possible to combine elements in different embodiments to form other embodiments.

For example, the substrate W may include the first region R1, and the second region R2 having an opening on the first region R1. The first region R1 may include at least one selected from a carbon containing-film and a metal containing-film. The second region R2 may be a stacked film including a silicon oxide film and a silicon nitride film.

Here, various embodiments included in the present disclosure are described in [E1] to [E8] below.

[E1] A substrate processing method including:
(a) preparing a substrate having a first region containing a first material, and a second region containing a second material different from the first material;
(b) forming a metal-containing deposit on the first region by using first plasma generated from a first processing gas containing at least one of carbon and hydrogen, fluorine, and metal;
(c) modifying at least a surface of the metal-containing deposit by using a second plasma generated from a second processing gas different from the first processing gas, after (b); and
(d) repeating (b) and (c).

The first processing gas may contain carbon but may not contain hydrogen, may contain hydrogen but may not contain carbon, or may contain both carbon and hydrogen.

According to the substrate processing method, in (c), a modified region is formed on at least the surface of the metal-containing deposit. After that, in (b) during (d), a metal-containing deposit is further formed on the modified region. A thicker metal-containing deposit is formed on the modified region compared to when the modified region is not present. Therefore, by adjusting the number of repetitions of (b) and (c), it is possible to control the thickness of the metal-containing deposit formed on the first region.

[E2] In the substrate processing method described in [E1], the second processing gas contains a hydrogen-containing gas.

[E3] In the substrate processing method described in [E1] or [E2], the metal-containing deposit contains metal oxide, and the second processing gas contains a reducing gas that reduces the metal oxide.

In this case, a metal region may be formed as the modified region.

[E4] In the substrate processing method described in any one of [E1] to [E3], the metal includes at least one selected from tungsten and molybdenum. [E5] In the substrate processing method described in [E4], the first processing gas contains at least one selected from tungsten halide gas and molybdenum halide gas.

[E6] In the substrate processing method described in any one of [E1] to [E5], the first processing gas contains a fluorine-containing gas.

[E7] In the substrate processing method described in any one of [E1] to [E6], the first processing gas contains at least one of a carbon-containing gas and a hydrogen-containing gas.

[E8] In the substrate processing method described in any one of [E1] to [E7], the first material contains silicon nitride, and the second material contains silicon oxide.

[E9] In the substrate processing method described in any one of [E1] to [E8], in (b), the second region is etched by the first plasma.

[E10] In the substrate processing method described in any one of [E1] to [E9], the first region has a recess, and the second region is present in the recess.

[E11] A substrate processing apparatus including:
a chamber;
a substrate support configured to support a substrate within the chamber, the substrate having a first region containing a first material, and a second region containing a second material different from the first material;
a gas supply configured to supply a first processing gas and a second processing gas different from the first processing gas, into the chamber, the first processing gas containing at least one of carbon and hydrogen, fluorine, and metal;
a plasma generator configured to generate first plasma and second plasma from the first processing gas and the second processing gas, respectively, within the chamber; and
a controller,
in which the controller is configured to control the gas supply and the plasma generator to:
   form a metal-containing deposit on the first region by using the first plasma,
   modify at least the surface of the metal-containing deposit by using the second plasma after the metal-containing deposit is formed, and
   repeat forming the metal-containing deposit and modifying at least the surface of the metal-containing deposit.

According to one embodiment, provided are a substrate processing method and a substrate processing apparatus in which the thickness of a metal-containing deposit can be controlled.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
(a) preparing a substrate having a first region containing a first material, and a second region containing a second material different from the first material;
(b) forming a metal-containing deposit on the first region by using a first plasma generated from a first processing gas containing at least one of carbon and hydrogen, fluorine, and metal;
(c) modifying at least a surface of the metal-containing deposit by using a second plasma generated from a second processing gas different from the first processing gas, after (b); and
(d) repeating (b) and (c).

2. The substrate processing method according to claim 1, wherein the second processing gas contains a hydrogen-containing gas.

3. The substrate processing method according to claim 1, wherein
the metal-containing deposit contains metal oxide, and
the second processing gas contains a reducing gas that reduces the metal oxide.

4. The substrate processing method according to claim 1, wherein the metal includes at least one selected from tungsten and molybdenum.

5. The substrate processing method according to claim 4, wherein the first processing gas contains at least one selected from tungsten halide gas and molybdenum halide gas.

6. The substrate processing method according to claim 1, wherein the first processing gas contains a fluorine-containing gas.

7. The substrate processing method according to claim 1, wherein the first processing gas contains at least one of a carbon-containing gas and a hydrogen-containing gas.

8. The substrate processing method according to claim 1, wherein
the first material contains silicon nitride, and
the second material contains silicon oxide.

9. The substrate processing method according to claim 1, wherein in (b), the second region is etched by the first plasma.

10. The substrate processing method according to claim 1, wherein the first region has a recess, and the second region is present in the recess.

11. A substrate processing apparatus comprising:
a chamber;
a substrate support configured to support a substrate within the chamber, the substrate having a first region containing a first material, and a second region containing a second material different from the first material;
a gas supply configured to supply a first processing gas and a second processing gas different from the first processing gas, into the chamber, the first processing gas containing at least one of carbon and hydrogen, fluorine, and metal;
a plasma generator configured to generate a first plasma and a second plasma from the first processing gas and the second processing gas, respectively, within the chamber; and
a controller,
wherein the controller is configured to control the gas supply and the plasma generator to:
form a metal-containing deposit on the first region by using the first plasma,
modify at least the surface of the metal-containing deposit by using the second plasma after the metal-containing deposit is formed, and
repeat forming the metal-containing deposit and modifying at least the surface of the metal-containing deposit.
